(19) United States
(12) Patent Application Publication
(10) Pub. No.: US 2012/0313891 A1
(43) Pub. Date: Dec. 13, 2012

(54) DISTANCE SENSING CIRCUIT AND TOUCH-CONTROL ELECTRONIC APPARATUS

(75) Inventors: WEI-CHUNG CHANG, HSINCHU COUNTY (TW); CHIA-HUANG LIN, HSINCHU COUNTY (TW); MING-HUANG LIU, HSINCHU COUNTY (TW)

(73) Assignee: SITRONIX TECHNOLOGY CORP, HSINCHU COUNTY (TW)

(21) Appl. No.: 13/489,553

(22) Filed: Jun. 6, 2012

(30) Foreign Application Priority Data
Jun. 8, 2011 (TW) 100119913

(51) Int. Cl. G06F 3/044; G01R 27/26

(52) U.S. Cl. 345/174; 324/679; 178/18.06

(57) ABSTRACT

The present invention discloses a distance sensing circuit and a touch-control electronic apparatus. The touch-control electronic apparatus includes a distance sensing circuit. The distance sensing circuit comprises a distance sensing unit, a capacitive sensing unit, and an operation unit. The distance sensing unit senses the distance between an object and the touch-control electronic apparatus and generates a first sensing signal. The capacitive sensing unit generates a second sensing signal corresponding to the object. The operation unit judges the distance between the touch-control electronic apparatus and the object according to the first and the second sensing signals. The touch-control electronic apparatus according to the present invention can truly judge the distance between itself and the object by means of the distance sensing unit and the capacitive sensing unit for controlling touch-control functions of the touch-control electronic apparatus.

### FIELD OF THE INVENTION

The present invention relates generally to a sensing circuit and a touch-control electronic apparatus, and particularly to a sensing circuit and a touch-control electronic apparatus capable of improving sensing accuracy.

### BACKGROUND OF THE INVENTION

In the modern information society, the reliance of people on electronic products is increasing day by day. Electronic products, such as mobile phones, handheld PCs, personal digital assistants (PDAs), are prevalent in people's lives, making them indispensable. Electronic products with friendly interfaces and excellent functions are provided continuously. Taking mobile phones for example, with the advancement of manufacturing technologies and reduction of costs, they are very popular in the market and have become one of the communication tools used most frequently, almost to the extent that everyone owns one.

Nowadays, in order to increase function for handheld electronic devices such as mobile phones, distance sensors are applied thereto, especially to mobile phones having touch-control functions. The major purpose is that the touch-control functions need to be disabled when user operates the mobile phone and the mobile phone is near to the user. It is for avoiding false touches on the touch screen of the mobile phone, which will execute other functions falsely. For example, when a user operates the mobile phone having touch-control functions for calling, the mobile phone will be close to the user's head, ear, and face. Consequently, the ear or the face may touch falsely the other functional options, such as “hang up”, on the touch screen of the mobile phone and hence affecting the user's call. The mobile phone can detect the distance between the user's head, ear, or face and the mobile phone itself by means of a distance sensor, so that the touch-control functions thereof are disabled when the mobile phone is close to the user's head, ear, or face, and thus preventing the other functional options on the touch screen of the mobile phone from false touches. In addition, when the user does not operate the mobile phone and places it on a table with its screen facing downwards, the distance sensor can also sense the distance between the surface of the table and the mobile phone and hence giving that the mobile phone is not used and is placed on the table. Accordingly, some parts of functions of the mobile phone, such as the display or the touch-control functions, can be turned off and thus saving power.

The current distance sensor in common use is an optical distance sensor, which emits light to an object and the object will reflect the light back to the optical distance sensor. The optical distance sensor senses the intensity of the reflected light and generates a sensing signal with corresponding intensity. Thereby, according to the intensity of the sensing signal, the distance between the object and the optical distance sensor is given. In general applications, when the mobile phone having touch-control functions enters the calling mode, the user moves the mobile phone close to the head, the face, and the ear. Because the optical distance sensor is closer to the head, the face or the ear, they will be illuminated by light with stronger intensity, and hence making that the intensity of the reflected light from the head, the face or the ear is relatively stronger. Consequently, the intensity of the sensing signal generated by the optical distance sensor according to the reflected light is stronger. The mobile phone then knows that it is close to the user according to the sensing signal, and thus disabling its touch-control functions for preventing the other functional options on the touch screen of the mobile phone from false touches.

On the other hand, when the user ends calling, he/she will move the mobile phone away from the head, the face, and the ear. At this time, the optical distance sensor is relatively distant from the head, the face, and the ear, making the intensity of the light reflected back to the optical distance sensor from the head, the face, or the ear is relatively weaker. Thereby, the intensity of the sensing signal generated by the optical distance sensor according to the reflected light attenuates. Consequently, the mobile phone knows that it is away from the user according to the sensing signal with weaker intensity, and hence resuming the touch-control functions for the user.

In general, the optical distance sensor will add some mechanism for eliminating stray light. But, it blocks reflected light when the object is truly close to the optical distance sensor and causing the reflected light unable to propagate to the light-sensing area of the optical distance sensor. Hence, the optical distance sensor is unable to sense light, and the intensity of the sensing signal generated by the optical distance sensor attenuates. Accordingly, the mobile phone will misjudge that it is away from the object and then resuming the touch-control functions thereof. Under such a circumstance, the user may falsely touch the touch screen of the mobile phone during a call, and then execute the other functions and pause the call, leading to his/her inconvenience. Consequently, how to solve the drawbacks of conventional distance sensor and enhance the sensing accuracy of the distance sensor for improving performance of the touch-control electronic apparatus have become a major subject today.

Accordingly, the present invention provides a distance sensing circuit and a touch-control electronic apparatus for solving the problems described above. According to the present invention, the drawbacks described above can be improved, and false judgments made by the touch-control electronic apparatus can be avoided as well.

### SUMMARY

An objective of the present invention is to provide a distance sensing circuit, which uses a capacitive sensing unit and a distance sensing unit to sense the distance between the distance sensing unit and an object. Thereby, the purpose of enhancing sensing accuracy is achieved.

Another objective of the present invention is to provide a touch-control electronic apparatus, which can truly judge the distance between itself and an object for controlling touch-control functions. Thereby, the purpose of improving performance of the touch-control electronic apparatus is achieved.

The distance sensing circuit according to the present invention comprises a distance sensing unit, a capacitive sensing unit, and an operation unit. The distance sensing unit is used for sensing the distance between an object and the distance sensing unit and generating a first sensing signal. The capacitive sensing unit generates a second sensing signal corresponding to the object. The operation unit judges the distance between the distance sensing unit and the object according to the first and the second sensing signals. The distance sensing circuit according to the present invention senses the object by means of the distance sensing circuit and the capacitive sensing unit and hence achieving the purpose of enhancing sensing accuracy.

The touch-control electronic apparatus according to the present invention comprises a touch-control module, a distance sensing unit, a capacitive sensing unit, and an operation unit. The distance sensing unit is used for sensing the distance between an object and the touch-control electronic apparatus and generating a first sensing signal. The capacitive sensing unit generates a second sensing signal corresponding to the object. The operation unit judges the distance between the touch-control electronic apparatus and the object according to the first and the second sensing signals for controlling touch-control functions of the touch-control module.

### BRIEF DESCRIPTION OF THE DRAWINGS

FIG. 1 shows a block diagram of a distance sensing circuit and a touch-control electronic apparatus according to an embodiment of the present invention;

FIG. 2 shows a flowchart according to an embodiment of the present invention; and

FIG. 3 shows a flowchart according to another embodiment of the present invention.

### DETAILED DESCRIPTION

In order to make the structure and characteristics as well as the effectiveness of the present invention to be further understood and recognized, the detailed description of the present invention is provided as follows along with embodiments and accompanying figures.

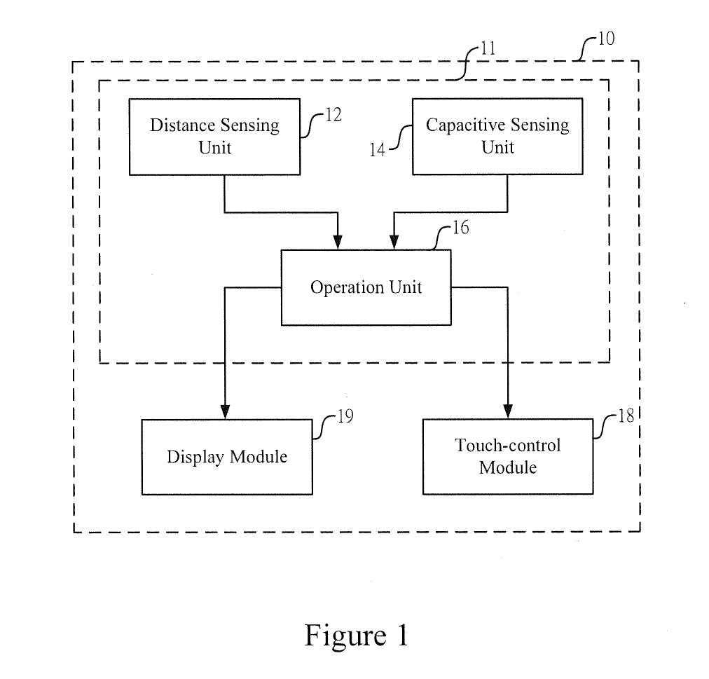

FIG. 1 shows a block diagram of a distance sensing circuit and a touch-control electronic apparatus according to an embodiment of the present invention. As shown in the figure, the distance sensing circuit 11 according to the present invention comprises a distance sensing unit 12, a capacitive sensing unit 14, and an operation unit 16. The distance sensing unit 12 is used for sensing the distance between an object (not shown in the figure) and the distance sensing unit 12 and generating a first sensing signal correspondingly. An embodiment of the distance sensing unit 12 according to the present invention is an optical distance sensor. The intensity of the first sensing signal generated by the distance sensing unit 12 is related to the distance between the distance sensing unit 12 and the object. Theoretically, if the distance sensing unit 12 is close to the object, the intensity of the first sensing signal is stronger. On the contrary, if the distance sensing unit 12 is away from the object, the intensity of the first sensing signal attenuates.

Referring to FIG. 1, as the capacitive sensing unit 14 is close to the object, its capacitance changes, and hence generating a second sensing signal correspondingly. The intensity of the second sensing signal is related to the distance between the capacitive sensing unit 14 and the object. If the capacitive sensing unit 14 is close to the object, the change in the intensity of the second sensing signal is relatively larger. On the other hand, if the capacitive sensing unit 14 is away from the object, the change in the intensity of the second sensing signal is smaller. The operation unit 16 is coupled to the distance sensing unit 12 and the capacitive sensing unit 14 for receiving the first sensing signal generated by the distance sensing unit 12 and the second sensing signal generated by the capacitive sensing unit 14 and judging the distance between the distance sensing unit 12 and the object according to the first and the second sensing signals. Thereby, even if the distance sensing unit 12 is very close to the object and generates a very weak first sensing signal, the intensity of the second sensing signal generated by the capacitive sensing unit 14 will not attenuate significantly. Hence, the operation unit 16 will judge that the distance sensing unit 12 is close to the object in instead of the distance sensing unit 12 is away from the object. No misjudgment will occur.

The distance sensing unit 12 and the capacitive sensing unit 14 of the distance sensing circuit 11 can be integrated into a single chip or can be independent devices. In addition, the distance sensing unit 12, the capacitive sensing unit 14, and the operation unit 16 according to the present invention can also be integrated into a single chip. The distance sensing circuit 11 according to the present invention can be applied to any kinds of electronic apparatuses for sensing the distance between the electronic apparatuses and an object and then executing specific functions. The distance sensing circuit 11 according to the present embodiment is disposed in a touch-control electronic apparatus 10. Namely, the touch-control electronic apparatus 10 according to the present invention comprises a distance sensing circuit 11 used for sensing the distance between the touch-control electronic apparatus 10 and an object, which can be any article or living body. For example, the distance sensing circuit 11 senses the distance between the touch-control electronic apparatus 10 and the user or the table. Because the distance sensing circuit 11 according to the present embodiment is disposed in the touch-control electronic apparatus 10, the distance sensing unit 12 is used for sensing the distance between an object and the touch-control electronic apparatus 10 and generating the first sensing signal correspondingly.

The touch-control electronic apparatus 10 has a touch-control module 18 used for proving touch-control functions. Thereby, a user can touch the touch screen of the touch-control electronic apparatus 10 for operating touch-control electronic apparatus 10 and executing various functions thereof. The touch-control module 18 includes hardware circuits and touch-control software executed by the internal operation unit of the touch-control apparatus 10. These are general for a person having ordinary skill in the art and hence will not be described any further. When the distance sensing circuit 11 according to the present invention is applied to the touch-control electronic apparatus 10, the distance sensing unit 12 and the capacitive sensing unit 14 can be disposed additionally inside the touch-control electronic apparatus 10. Besides, if the touch-control electronic apparatus 10 adopts capacitive touch control, the capacitive sensing circuit in the touch-control module 18 can be used as the capacitive sensing unit 14 of the distance sensing circuit 11 according to the present invention. Thereby, no extra capacitive sensing unit 14 is required, and thus saving costs and avoiding increase in the volume of the touch-control electronic apparatus 10. Moreover, the operation unit 16 of the distance sensing circuit 11 can be used as the operation unit inside the touch-control electronic apparatus 10, such as the processor.

In the present embodiment, the operation unit 16 judges the distance between the touch-control electronic apparatus 10 and the object according to the first and the second sensing signals for controlling the touch-control functions of the touch-control module 18. According to an embodiment of the present invention, the operation unit 16 compares the first and the second sensing signals with two threshold values, respectively. If they are smaller than the two threshold values, respectively, the operation unit 16 judges that the touch-control electronic apparatus 10 is away from the object. Nonetheless, if the first sensing signal is smaller than the first threshold value while the second sensing signal is greater than the other threshold value, the operation unit 16 judges that the touch-control electronic apparatus 10 is close to the object. Thereby, influences on the accuracy of distance sensing due to the drawback of the inability of the distance sensing unit 12 to true sense can be avoided when the touch-control electronic apparatus 10 is too close to the object.

When the operation unit 16 judges that the touch-control electronic apparatus 10 is close to the object, for example, when the user talks on the phone by using the touch-control electronic apparatus 10, the operation unit 16 will disable the touch-control functions of the touch-control electronic apparatus 10, namely, the touch-control functions provided by the touch-control module 18. Thereby, false touches by the user on the other functional options displayed on the touch screen (not shown in the figure) of the touch-control electronic apparatus 10 can be prevented.

In addition, when the operation unit 16 judges that the touch-control electronics apparatus 10 is moved away from the object, the operation unit 16 would enable the touch-control functions of the touch-control module 18. An embodiment of disabling the touch-control functions of the touch-control module 18 is to turn off the touch sensing circuit, for example, the capacitive sensing circuit or the resistive sensing circuit, in the touch-control module 18. Another embodiment is that the operation unit 16 drives the touch-control electronic apparatus 10 not to execute any touch-control software. The means according to the present invention for disabling the touch-control functions is variable, and therefore the present invention is not limited to above two embodiments. Besides, when the operation unit 16 according to the present invention judges that the touch-control electronic apparatus 10 is close to the object, the other functions, such as the display module 19 of the touch-control electronic apparatus 10, can be turned off for saving power. The functions are resumed when the operation unit 16 judges that the touch-control electronic apparatus 10 is away from the object.

The distance sensing circuit 11 according to the present invention uses the distance sensing unit 12 together with the capacitive sensing unit 14 for solving the problem of inability of the distance sensing unit 12 to truly sense the object due to its own drawback when the object is too close to it. Thereby, the second sensing signal generated by the capacitive sensing unit 14 corresponding to the object can be used as the auxiliary signal for the operation unit 16. It can complement the drawback of the inability of the distance sensing unit 12 to truly sense the object when the object is too close to the distance sensing unit 12. Accordingly, the accuracy of the distance sensing circuit 11 in sensing distance is enhanced.

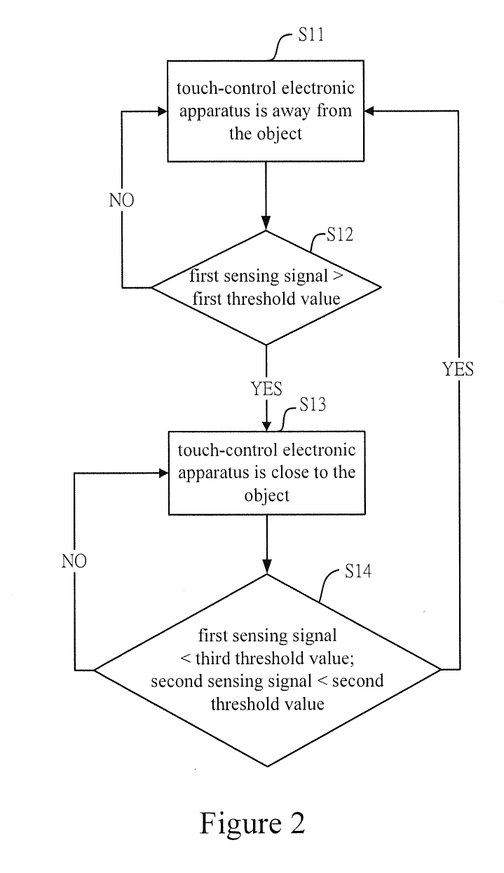

FIG. 2 shows a flowchart according to an embodiment of the present invention. This flowchart is the method by which the operation unit 16 judges that an electronic apparatus is close to or away from an object. For easier description, in the following, the touch-control electronic apparatus 10 is used for example. As shown in the step S11 of FIG. 2, when the user starts to operate the touch-control electronic apparatus 10, the touch-control electronic apparatus 10 is away from the object. According to the present embodiment, the touch-control electronic apparatus 10 is away from the user. At this time, the intensity of the first sensing signal generated by the distance sensing unit 12 is small, and the intensity of the second sensing signal generated by the capacitive sensing unit 14 is also small. When the user moves the touch-control electronic apparatus 10, the intensity of the first sensing signal and that of the second sensing signal vary according to the distance between the touch-control electronic apparatus 10 and the user, or, alternatively, and another object such as a table.

As shown in the step S12, the operation unit 16 compares the first sensing signal with a first threshold value. If the intensity of the first sensing signal is smaller than the first threshold value, the operation unit 16 judges that the touch-control electronic apparatus 10 is still away from the object. In other words, the touch-control electronic apparatus 10 is away from the user or the table. Hence, execution of the touch-control functions is maintained. On the contrary, if the intensity of the first sensing signal is greater than the first threshold value, as shown in S13, the operation unit 16 judges that the touch-control electronic apparatus 10 is close to the object. In the present embodiment, it means that the touch-control electronic apparatus 10 is close to the user. The touch-control electronic apparatus 10 will disable the touch-control functions thereof for preventing the other touch-control functions displayed on the touch screen of the touch-control electronic apparatus 10 from false touches.

The touch-control electronic apparatus 10 judges that the touch-control electronic apparatus 10 is close to the object, it will continue receiving the first and the second sensing signals for judging if the user moves the touch-control electronic apparatus 10. The present invention further uses a third threshold value and a second threshold value for comparing with the first sensing signal generated by the distance sensing unit 12 and with the second sensing signal generated by the capacitive sensing unit 14, respectively. As shown in the step S14, when the intensity of the first sensing signal is smaller than the third threshold value and the intensity of the second sensing signal is smaller than the second threshold value, the operation unit 16 judges that the touch-control electronic apparatus 10 is away from the object. Namely, the touch-control electronic apparatus 10 is away from the user. Thereby, the operation unit 16 will drive the touch-control electronic apparatus 10 to resume executing the touch-control functions. If the intensity of the first sensing signal is smaller than the third threshold value and the intensity of the second sensing signal is greater than the second threshold value, the operation unit 16 will judges that the touch-control electronic apparatus 10 is close to the object and hence keeping disabling the touch-control functions. Accordingly, influences on the accuracy of distance sensing due to the drawback of the inability of the distance sensing unit 12 to true sensing can be avoided when the touch-control electronic apparatus 10 is too close to the object.

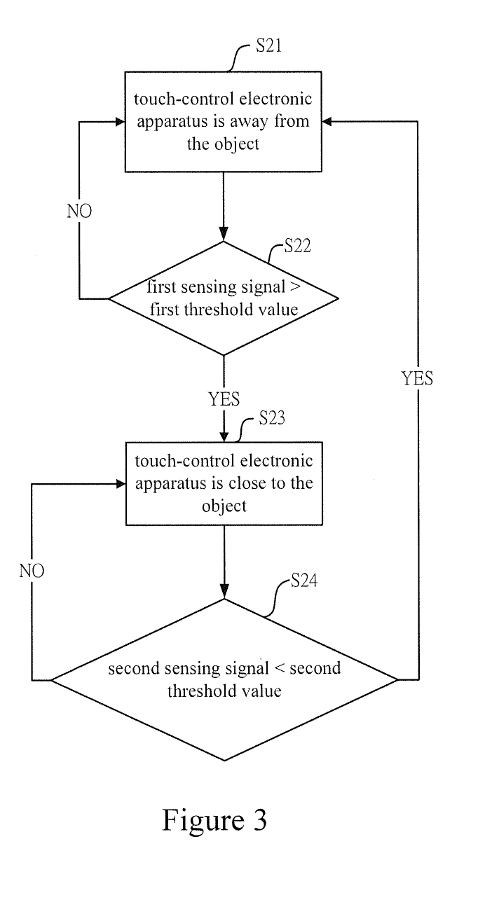

FIG. 3 shows a flowchart according to another embodiment of the present invention. As shown in the figure, the step S24 according to the present embodiment is different from the step S14 according to the previous embodiment. The other steps S21 to S23 are the same as the steps S11 to S13 in the previous one. When the operation unit 16 according to the present embodiment compares and know that the intensity of the first sensing signal is greater than the first threshold value, it judges that the touch-control electronic apparatus 10 is close to the object. Afterwards, as shown in the step S24, the operation unit 16 only compares the second sensing signal with the second threshold value. If the intensity of the second sensing signal is smaller than the second threshold value, the operation unit 16 judges that the touch-control electronic apparatus 10 is away from the object. Otherwise, it judges that the touch-control electronic apparatus 10 is still close to the object.

The present invention provides a distance sensing circuit and a touch-control electronic apparatus. The touch-control electronic apparatus includes a distance sensing circuit for truly sensing the distance between the touch-control electronic apparatus and an object and for controlling touch-control functions of the touch-control electronic apparatus. The distance sensing circuit senses the distance between the object and the touch-control electronic apparatus and generates a first sensing signal by means of a distance sensing unit. A capacitive sensing unit generates a second sensing signal corresponding to the object. An operation unit of the distance sensing circuit judges the distance between the touch-control electronic apparatus and the object according to the first and the second sensing signals for controlling the touch-control functions of the touch-control electronic apparatus. The touch-control electronic apparatus according to the present invention can truly judge the distance between itself and the object by means of the distance sensing unit and the capacitive sensing unit. Thereby, the accuracy of sensing distance is improved.

Accordingly, the present invention conforms to the legal requirements owing to its novelty, nonobviousness, and utility. However, the foregoing description is only embodiments of the present invention, not used to limit the scope and range of the present invention. Those equivalent changes or modifications made according to the shape, structure, feature, or spirit described in the claims of the present invention are included in the appended claims of the present invention.

1. A distance sensing circuit, comprising:
a distance sensing unit, sensing the distance between an object and said distance sensing unit, and generating a first sensing signal;
a capacitive sensing unit, generating a second sensing signal corresponding to said object; and
an operation unit, judging the distance between said distance sensing unit and said object according to said first sensing signal and said second sensing signal.

2. The distance sensing circuit as claimed in claim 1, wherein said distance sensing unit, said capacitive sensing unit, and said operation unit are disposed in an electronic apparatus.

3. The distance sensing circuit as claimed in claim 2, wherein said operation unit compares said first sensing signal with a first threshold value, and when said first sensing signal is greater than said first threshold value, said operation unit judges that said electronic apparatus is close to said object.

4. The distance sensing circuit as claimed in claim 3, wherein said operation unit compares said first sensing signal with a third threshold value and said second sensing signal with a second threshold value, and when said first sensing signal is smaller than said third threshold value and said second sensing signal is smaller than said second threshold value, respectively, said operation unit judges that said electronic apparatus is away from said object.

5. The distance sensing circuit as claimed in claim 3, wherein said operation unit compares said second sensing signal with a second threshold value, and when said second sensing signal is smaller than said second threshold value, said operation unit judges that said electronic apparatus is away from said object.

6. The distance sensing circuit as claimed in claim 2, wherein said electronic apparatus is a touch-control electronic apparatus.

7. The distance sensing circuit as claimed in claim 1, wherein said distance sensing unit is an optical distance sensor.

8. A touch-control electronic apparatus, comprising:
a touch-control module, proving a touch-control function;
a distance sensing unit, sensing the distance between an object and said touch-control electronic apparatus, and generating a first sensing signal;
a capacitive sensing unit, generating a second sensing signal corresponding to said object; and
an operation unit, judging the distance between said touch-control electronic apparatus and said object according to said first sensing signal and said second sensing signal for controlling said touch-control function of said touch-control module.

9. The touch-control electronic apparatus as claimed in claim 8, wherein said operation unit compares said first sensing signal with a first threshold value, and when said first sensing signal is greater than said first threshold value, said operation unit judges that said touch-control electronic apparatus is close to said object and then disables said touch-control function of said touch-control module.

10. The touch-control electronic apparatus as claimed in claim 9, wherein said operation unit compares said first sensing signal with a third threshold value and said second sensing signal with a second threshold value, and when said first sensing signal is smaller than said third threshold value and said second sensing signal is smaller than said second threshold value, respectively, said operation unit judges that said touch-control electronic apparatus is away from said object and then turns on said touch-control function of said touch-control module.

11. The touch-control electronic apparatus as claimed in claim 9, wherein said operation unit compares said second sensing signal with a second threshold value, and when said second sensing signal is smaller than said second threshold value, said operation unit judges that said touch-control electronic apparatus is away from said object and then turns on said touch-control function of said touch-control module.

12. The touch-control electronic apparatus as claimed in claim 8, wherein said distance sensing unit is an optical distance sensor.
